(19) United States
(12) Patent Application Publication
(10) Pub. No.: US 2007/0229115 A1
(43) Pub. Date: Oct. 4, 2007

(54) Method and apparatus for correcting duty cycle error in a clock distribution network

(75) Inventors: Charlie Chornglii Hwang, Hopewell Junction, NY (US); Phillip John Restle, Katonah, NY (US); Michael George Robert Thomson, Bedford, NY (US)

Correspondence Address: Ryan, Mason & Lewis, LLP, 90 Forest Avenue, Locust Valley, NY, 11560, US

(73) Assignee: International Business Machines Corporation, Armonk, NY (US)

(21) Appl. No.: 11/339,124

(22) Filed: Jan. 25, 2006

(51) Int. Cl. H03M 7/00; H03K 19/00

(52) U.S. Cl. 326/93

(57) ABSTRACT

A clock distribution network for distributing a repetitive timing signal throughout an integrated circuit, the timing signal being within a range of frequencies about a first frequency, includes multiple buffer circuits and at least one conductive segment connecting one of the buffers to another of the buffers. The conductive segment has a length selected so as to be less than a quarter-wave resonance length of the conductive segment at the first frequency to thereby achieve duty cycle correction.

### FIELD OF THE INVENTION

The present invention relates generally to clock distribution circuitry, and more particularly relates to techniques for correcting duty cycle error in a clock distribution network.

### BACKGROUND OF THE INVENTION

In many high-performance very large scale integration (VLSI) chips, including, for example, microprocessor chips, a reference clock signal, which may be generated externally and supplied to the chip, is distributed globally throughout the chip using a wiring network. The wiring network, which is typically either a tree-based network, a grid-based network, or a combination of a tree-based and a grid-based network, is re-powered at a number of points by buffers. Each buffer ideally generates a signal that is identical to the original reference clock signal. FIG. 1 illustrates a conventional grid tree network 100 including a central re-powering buffer 102 which receives the clock signal and distributes it throughout the chip using a plurality of buffers 102 and corresponding wiring 104. It is essential that the signals generated by the various buffers arrive at their respective destinations throughout the chip as simultaneously as possible so as to minimize clock skew, or arrive with precisely known timing differences so as to facilitate appropriate compensation of clock delays.

A clock signal generally comprises a logic “high” portion and a logic “low” portion. A desired characteristic of a global clock distribution architecture is that it ideally exhibits a 50 percent duty cycle, meaning that the duration of the logic high pulse in the clock signal is exactly 50 percent of the full clock cycle. Thus, the duration of the logic high portion of the clock signal is ideally the same as the duration of the logic low portion of the clock signal for any given clock cycle. Due to model inaccuracies and process, voltage and/or temperature (PVT) variations to which the chip is subjected, rising and falling edges of the clock signal are transmitted with slightly different delays resulting in a duty cycle error. Duty cycle error may be defined herein as the difference between the actual duty cycle and the desired 50 percent duty cycle. In addition, buffered clock distributions employing wires that are represented only by resistance (R) and capacitance (C) are known to be unstable with respect to duty cycle error in the sense that any duty cycle error will be increased by the clock distribution network.

Timing errors attributable to duty cycle error can significantly degrade the overall performance and/or reliability of the chip, and it is therefore beneficial to minimize such duty cycle error. Some advanced circuit techniques, such as, for example, limited switch dynamic logic (LSDL), are especially sensitive to duty cycle error. This problem becomes even more pronounced as the total clock delay between the clock source and the various destination points in the chip exceeds one clock cycle. For instance, the expected duty cycle error from a clock distribution network having a total clock delay of four cycles is approximately four times as large as the duty cycle error expected from a clock distribution network having a one cycle clock delay.

Solutions for reducing duty cycle error are well known, such as, for example, using differential clock distribution architectures, or employing active and/or passive duty cycle correction circuits. However, these known approaches are often complex or require additional design and testing resources, and are therefore undesirable. Moreover, PVT variations can cause the duty cycle to vary substantially from one chip to another, thereby requiring individual integrated circuit (IC) configuration to correct the duty cycle error on each chip which can significantly increase testing time and cost.

Accordingly, there exists a need for techniques for reducing duty cycle error in a clock distribution network that do not suffer from one or more of the problems exhibited by conventional clock distribution architectures and methodologies.

### SUMMARY OF THE INVENTION

The present invention meets the above-noted need by providing, in an illustrative embodiment, techniques for reducing duty cycle error associated with a repetitive high-frequency timing signal (e.g., a global clock signal) in an IC device.

In accordance with one aspect of the invention, a clock distribution network for distributing a repetitive timing signal throughout an integrated circuit, the timing signal being within a range of frequencies about a first frequency, includes multiple buffer circuits and at least one conductive segment connecting one of the buffers to another of the buffers. The conductive segment has a length selected so as to be less than a quarter-wave resonance length of the conductive segment at the first frequency to thereby achieve duty cycle correction. The length of the conductive segment is preferably selected such that a time taken for the timing signal to traverse the conductive segment follows the relation

$$\frac{P}{8 n + 2} < T < \frac{P}{8 n - 2} ,$$

where T represents the time taken for the timing signal to traverse the at least one conductive segment, P represents a period of the timing signal, and n represents a positive integer based on at least one of harmonics of a resonance of the conductive segment and harmonics of a frequency of the timing signal.

In accordance with another aspect of the invention, a method of reducing duty cycle error of a repetitive timing signal in a clock distribution network including a plurality of buffers and a plurality of conductive segments, each of the plurality of conductive segments providing electrical connection between a respective pair of buffers in the plurality of buffers, includes the steps of: adjusting an output impedance of a first buffer of a given pair of buffers so that the output impedance of the first buffer is less than a characteristic impedance of a given one of the conductive segments, the first buffer having an output connected to the given conductive segment; adjusting an input impedance of a second buffer of the given pair of buffers so that the input impedance of the second buffer is greater than the characteristic impedance of the given conductive segment; and adjusting a length of the given conductive segment so that a time taken by the timing signal to traverse the given conductive segment is less than a quarter-wave resonance length of the conductive segment at a frequency of operation of the timing signal.

In accordance with a third aspect of the invention, one or more clock distribution networks and/or the method of reducing duty cycle error is implemented in an integrated circuit.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 illustrates a conventional grid tree clock distribution network.

FIG. 2A is a schematic diagram depicting at least a portion of an illustrative clock distribution network in which techniques of the present invention can be implemented.

FIG. 2B shows waveforms illustrating duty cycle degradation as a clock signal is transmitted across a chip using unoptimized wire segments between buffers and waveforms illustrating a reduction in duty cycle degradation achieved using optimized wire segments, in accordance with the present invention.

FIG. 3 shows exemplary waveforms illustrating a buffer output driving a 2.5 millimeter wire segment for different duty cycles, in accordance with aspects of the present invention.

FIG. 4A is a graphical view illustrating duty cycle correction and sensitivity of driving buffer transit time to small increases in buffer strength, in accordance with aspects of the present invention.

FIG. 4B shows exemplary waveforms illustrating outputs of a nominal buffer and a 25 percent stronger buffer driving an 8 mm wire segment, in accordance with aspects of the invention.

FIG. 5 is an exemplary graphical view depicting potential effects of harmonic frequencies on delay sensitivity for increasing wire lengths using wire segments having artificially low losses, in accordance with an aspect of the invention.

FIG. 6 shows exemplary graphical views illustrating simulated and measured duty cycle correction results for a clock distribution network operating at a clock frequency of 5 gigahertz, in accordance with an embodiment of the invention.

FIG. 7 is a histogram depicting exemplary results for 200 clock edge measurements at two different locations on a chip, in accordance with aspects of the invention.

### DETAILED DESCRIPTION OF THE INVENTION

The present invention will be described herein in the context of an illustrative clock distribution network for use, for example, in a high-speed (e.g., greater than about one gigahertz (GHz)) microprocessor. It should be understood, however, that the present invention is not limited to clock distribution networks. Rather, the invention is more generally applicable to techniques for advantageously distributing a repetitive signal throughout an integrated circuit in such a manner as to reduce duty cycle error in the integrated circuit. The techniques of the invention can therefore be used for improving clock distribution characteristics in the integrated circuit, without the use of additional active or passive duty cycle correction (DCC) circuitry. Furthermore, aspects of the invention can be used to preserve the width of non-repetitive pulses that are distributed in an integrated circuit, as will become apparent to those skilled in the art using the techniques described herein.

When high-frequency signals (e.g., above about 1 GHz) are carried on wire segments, the wire segments behave as transmission lines. Therefore, when employing transmission lines of any significant length care must be taken that the transmission medium is matched to its terminations. Increasing clock frequencies and use of lower-loss transmission lines to carry the clock signal have resulted in wavelengths similar to optimal wire segment lengths for on-chip clock distribution. Generally, the source and load impedances should equal the characteristic impedance of the transmission line, as this minimizes signal reflections. Signal reflection occurs as a transmitted signal is at least partially reflected back toward its origin due to differences in impedance along the transmission line. The transmission lines on a given chip, however, are rarely driven nor terminated with their characteristic impedances, and therefore significant signal reflections will most likely occur. The degree of signal reflection will primarily be a function of the magnitude of the difference between the characteristic impedance of the wire segment and the load impedance at an end of the wire segment. If these signal reflection effects are not considered, the clock distribution may degrade overall chip performance.

Alternatively, in accordance with one aspect of the invention, signal reflection effects can be beneficially used to create a clock distribution network which reduces duty cycle errors, thereby enhancing the effective bandwidth of the clock distribution network, reducing the number of buffers required in the clock distribution network, and reducing clock jitter and skew. Known methodologies which attempt to reduce duty cycle error in a clock distribution network, which have conventionally involved the inclusion of active or passive DCC circuitry, are complex and require additional design and test resources, as previously stated. The addition of active or passive DCC circuitry is particularly undesirable in highly dense VLSI chips, such as, for example, microprocessors, where semiconductor area is already at a premium.

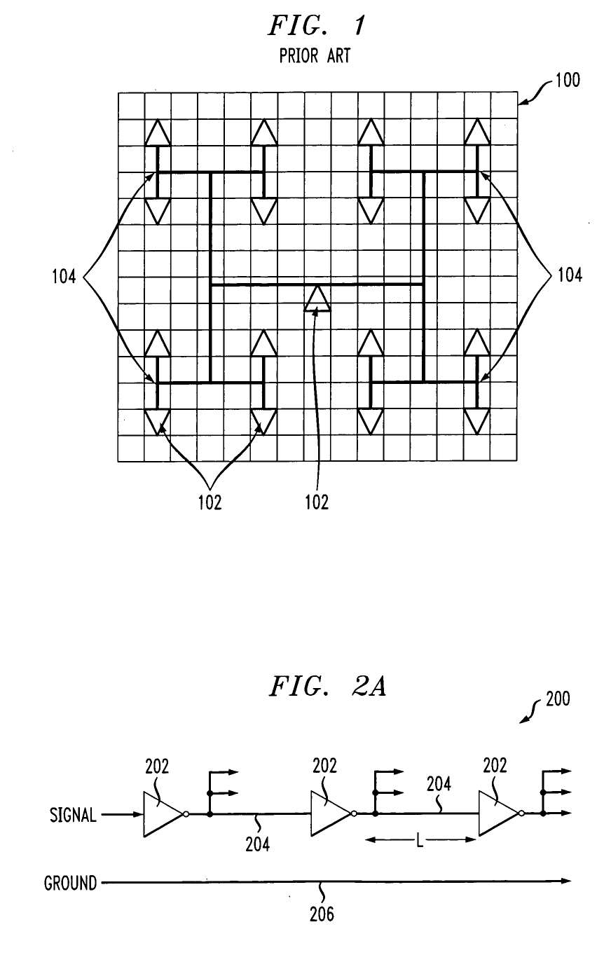

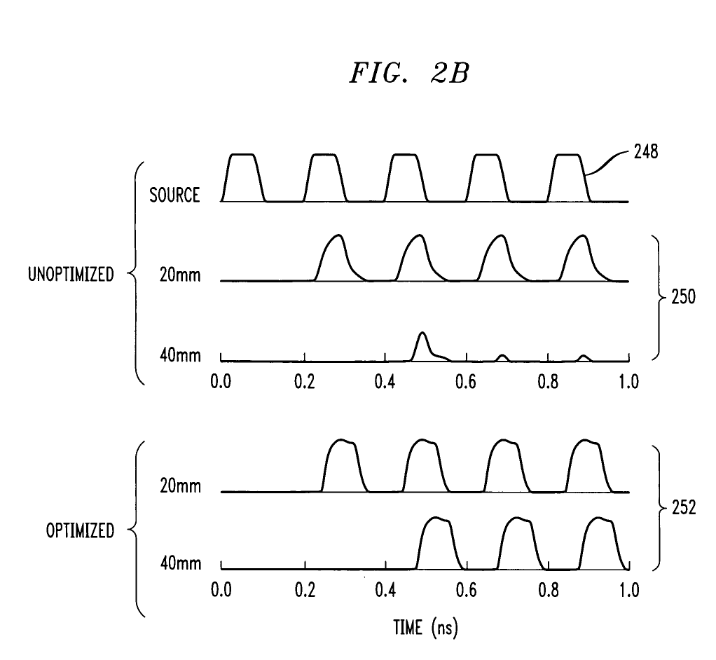

FIG. 2A illustrates at least a portion of an exemplary clock distribution network 200. The clock distribution network 200 includes a plurality of repower buffers 202 and a plurality of wire segments 204 for distributing a clock signal across a chip. Each of the wire segments 204, which may be modeled as a transmission line when the wire segment is in close relative proximity to a signal return conductor 206 (e.g., an alternating current (ac) ground), preferably connects an output of one buffer to an input of another buffer, as shown. In this embodiment, the wires segments 204 are of a fixed length L. In contrast to conventional methodologies, the present invention, in an illustrative embodiment thereof, advantageously utilizes signal reflection effects by optimizing the length L of the wire segments 204 and/or selecting appropriate buffer strengths for the buffers 202 in clock distribution network 200, to thereby reduce duty cycle errors. Buffer strength may be adjusted as desired by appropriately sizing one or more transistor devices in an output stage of the buffer 202. The output stage of a buffer typically comprises a p-channel field effect transistor (PFET) device and an n-channel field effect transistor (NFET) device connected as a standard inverter. Generally, the strength of a buffer is directly proportional to a channel width-to-length (W/L) ratio of the PFET and NFET devices in the buffer output stage, as will be understood by those skilled in the art. As the W/L ratio of the devices increases, buffer strength increases accordingly.

The term “wire segment” as used herein may be defined as any conductor used to convey an electrical signal or signals between two or more nodes. Wire segments need not be limited to any particular shape (e.g., straight, curved, etc.) or dimensions and may include, but are not limited to, integrated circuit traces, printed circuit board traces, etc., formed of a conductive material (e.g., metal, polysilicon, etc.). The term “wire segment” may be used synonymously herein with the terms “line,” “transmission line,” “line segment,” “wire,” etc.

Consider the case where the duty cycle of a driving buffer is less than 50 percent. FIG. 2B depicts exemplary simulation waveforms 250 illustrating the inevitable duty cycle degradation in the case of the simple clock distribution network 200 shown in FIG. 2A using unoptimized wire segment lengths, and exemplary simulation waveforms 252 illustrating a substantially reduced duty cycle degradation in the case of the clock distribution network employing optimized wire segment lengths. Waveforms 250 and 252 depict the duty cycle degradation in the clock distribution network 200 as the clock signal is transmitted increasing distances (e.g., 20 millimeters (mm) and 40 mm) across the chip from a source clock signal 248 (e.g., 5 GHz) using unoptimized and optimized wire segments, respectively, between buffers 202 (see FIG. 2A). When using simple RC wire models, such networks are known to exhibit increased duty cycle error. With on-chip transmission models, this behavior can be substantially changed by the effects of signal reflection at ends of the wire segments to thereby reduce duty cycle error.

Pulse transmission through the wire segments can be simulated using, for example, PowerSpice, which is commercially available from International Business Machines (IBM) Corp. (IBM), although alternative circuit simulation programs and modeling methodologies are similarly contemplated. At low frequencies (e.g., approximately 1 megahertz (MHz) or less), there may be a wide choice of signal return paths in the chip, some quite distant from the signal wire. At high frequencies (e.g., above about 1 GHz), however, only wires substantially proximate to the signal wire will provide an effective signal return path. Frequency-dependent transmission line models of the wires may be constructed using, for example, AQUAIA (see, e.g., I. M. Elfadel, et al., “AQUAIA: A CAD Tool for On-Chip Interconnect Modeling, Analysis, and Optimization,” Dig. Electr. Perf. Electronic Packaging, Vol. 11, pp. 337-340, Monterey, Calif., October 2002, which is incorporated by reference herein), developed by Ibrahim M. Elfadel and Alina Deutsch, although alternative on-chip interconnect modeling programs are similarly contemplated.

By way of example only, and without loss of generality, a copper distribution wire segment is preferably selected having dimensions of 3.0 micrometers (μm) wide and 1.2 μm thick, and with spaces of 1.3 μm between the wire segment and the nearest adjacent power supply or ground conductor. There would be no reflection at the end of the wire segment if the source and load impedances were precisely matched (i.e., equal) to the characteristic impedance of the wire segment. However, this is rarely the case. The characteristic impedance of the wire segment is about 50 ohms (Ω) in the present example, and the wire segment is terminated by the input of a field-effect transistor (FET) buffer having a substantially high input impedance (e.g., greater than about 1 megohm) and which presents a small capacitive load (e.g., about a few picofarads or less). To achieve full-swing clock signals, a driving buffer will typically have an output impedance which is substantially less than the characteristic impedance of the wire segment. Accordingly, signal reflection effects will almost always be present. These reflected waves will travel back and forth along the wire segment until their respective amplitudes are diminished, primarily by absorption of energy by the terminating resistances and/or transmission line losses.

Reflected waves have an important effect on the timing of rising and falling edges of the clock signal at both ends of the wire segment. When the duty cycle of the clock signal is exactly 50 percent, the time between the rising and falling edges will be substantially the same, and therefore the effects of the reflected waves on both rising and falling edges of the clock signal will be substantially the same. If, however, the duty cycle of the clock signal is not 50 percent, as is sometimes the case, the timing of the rising and falling edges of the clock signal can be influenced in different ways by the reflected waves. This makes sense since the clock signal is no longer symmetrical when the duty cycle is not 50 percent. One significant effect is that the arrival of a reflected wave at the output of the driving buffer can either aid or oppose the buffer output transition, and therefore change the buffer delay and/or slew rate. Furthermore, when a reflected wave opposes the buffer output transition, the buffer may consume more power in order to generate a desired output signal. Since a given chip often includes many buffers, overall power consumption in the chip can significantly increase as a result of signal reflection effects.

By way of example only, assume that the velocity of pulses traveling along a given wire segment is 90 mm/nanosecond (ns). Using the expression c=λf, where c is pulse velocity (mm/ns), λ is wavelength (mm) and f is frequency (GHz), it can be determined that a 4.5 mm wire segment has a quarter-wave resonant frequency, F_{Q}, of 5 GHz. For a wire segment of this length, which may be referred to herein as the quarter-wave resonance length of the wire segment, a reflected pulse will return to the buffer output after a delay of 100 picoseconds (ps), coinciding with the next transition for a symmetric 5 GHz pulse train.

In accordance with one aspect of the invention, wire segment lengths are preferably selected such that the time taken by the clock signal to traverse the length of the wire segment follows the relation

$$\frac{P}{8 n + 2} < T < \frac{P}{8 n - 2} ,$$

where T is the time is takes the clock signal to travel the length of the wire segment, P is the clock period (1/f), and n is a positive integer which may be based, at least in part, on harmonics of the wire segment resonance and/or harmonics of the clock frequency. Assuming a typical case of n=1, the length of the wire segment is preferably selected such that the time taken by the clock pulses to travel the length of the wire segment is less than about one sixth and more than about one tenth of the clock period. By way of example only, optimal duty cycle correction for a 5 GHz clock signal occurs for a shorter wire segment length of about 2.5 mm (compared to the quarter-wave resonance length of about 4.5 mm), when the reflected pulse returns after a delay of only 55 ps, well before the next transition (e.g., rising edge or falling edge) of the clock signal. Duty cycle correction, as the term is used herein, is intended to refer to an adjustment of the duty cycle of a periodic signal having a measured duty cycle which is not exactly 50 percent so as make the duty cycle more closely equal to 50 percent.

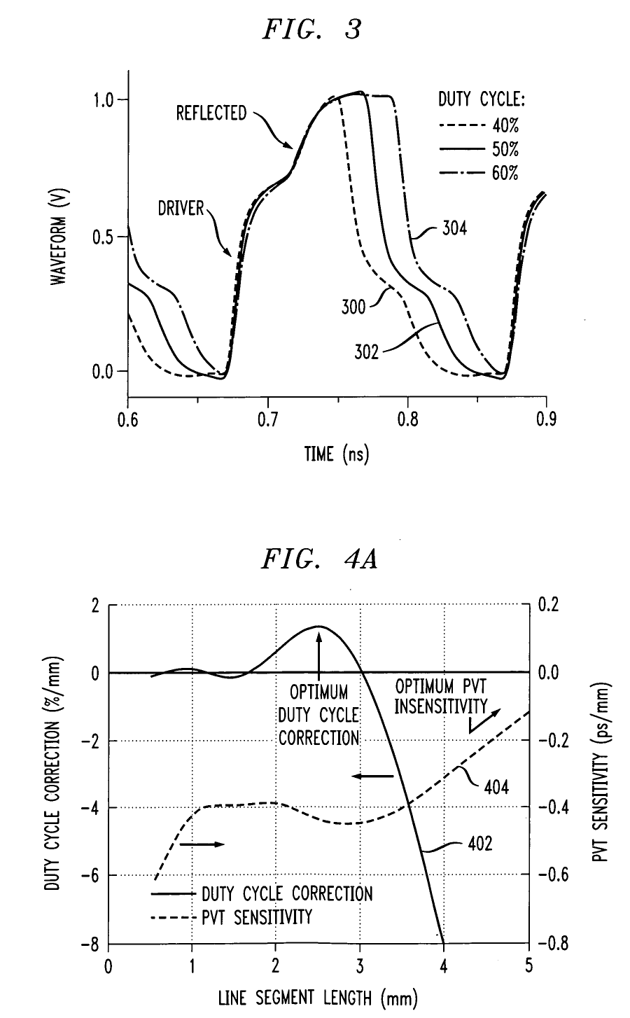

FIG. 3 shows exemplary waveforms, 300, 302 and 304, illustrating a buffer output driving a 2.5 mm wire segment for three different duty cycles, namely, 40 percent, 50 percent and 60 percent, respectively, in accordance with aspects of the invention. As apparent from the figure, a rising clock edge (“DRIVER” portion of the waveforms) leads to a rising reflected pulse after a short delay which pulls the buffer output further upwards (“REFLECTED” portion of the waveforms). With reference to waveform 300, at 40 percent duty cycle, the next falling transition of the clock signal occurs early, compared to a 50 percent duty cycle (waveform 302), and overlaps the reflected wave, which is still pulling the buffer output upwards, and it is delayed. With reference to waveform 304, at 60 percent duty cycle, the next falling transition of the clock signal arrives late, compared to a 50 percent duty cycle, and since the clock signal is no longer opposed by the reflected wave at this point, it suffers essentially no delay. A similar effect occurs for the falling edge of the clock signal, as will become apparent to those skilled in the art. Thus the length of a wire segment connected between an output of a driving buffer and an input of a next (repower) buffer is preferably selected, in accordance with aspects of the invention, so that the time it takes for the clock signal to travel the length of the wire segment and back is less than one clock period. This requires that the length of the wire segment be adapted so as to be less than a quarter-wave resonance length of the wire segment at the intended clock frequency of operation.

In this example, the buffer rising and falling delays are 9.9 ps when the duty cycle is 50 percent, but change to 11.8 ps and 9.2 ps, respectively, when the duty cycle falls to 40 percent. A 40 percent duty cycle effectively becomes 41.3 percent, and a 60 percent duty cycle becomes 59.1 percent, both of which are closer to the desired 50 percent duty cycle. Thus, in accordance with an aspect of the invention, by appropriate selection of the wire segment length, the signal reflection of one clock pulse is advantageously used to affect the timing (e.g., delay and slew) of the next clock pulse in the clock signal to thereby achieve a certain amount of duty cycle correction. A typical clock distribution network comprises many such wire segments connected in series between adjacent pairs of buffers (e.g., as shown in FIG. 2A), and therefore, collectively, significant duty cycle correction can beneficially be achieved throughout the chip.

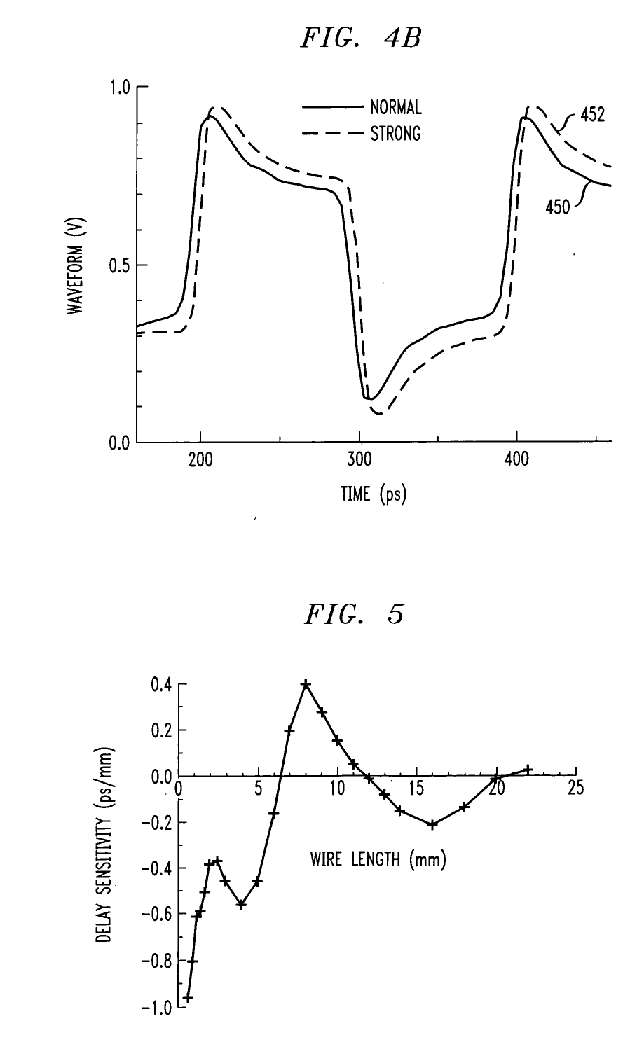

FIG. 4A shows exemplary graphical views, 402 and 404, illustrating duty cycle correction and sensitivity of driving buffer transit time to small increases in buffer strength, respectively, in accordance with aspects of the present invention. A first graphical view 402 shows the change in duty cycle at the end of the wire segment as a function of wire length using the same medium strength buffer for all cases. As apparent from the figure, optimal duty cycle correction occurs for a wire length of about 2.5 mm for the clock frequency (e.g., GHz) and buffer strength. It is to be appreciated that for a fixed wire length, duty cycle correction typically occurs over a range of frequencies. For example, in the present case, for a fixed wire length of 2.5 mm, suitable duty cycle correction occurs over a frequency range of approximately 3.6 GHz to about 6.1 GHz.

Another desired feature of clock distribution networks is insensitivity to PVT variations to which the buffers may be subjected. A second graphical view 404 shows the PVT sensitivity of the buffer to variations in buffer strength as a function of wire segment length. Using reflection effects and proper selection of wire segment lengths, it is possible to design buffered transmission line networks having positive, negative, or substantially zero sensitivity to buffer strength, in accordance with another aspect of the invention. In the exemplary case shown in FIG. 4A, it is apparent that the optimal wire length for duty cycle correction is shorter than the quarter-wave resonant length of about 4.0 mm. In contrast, the optimal wire length for buffer PVT insensitivity is longer than the quarter-wave resonant length (e.g., greater than 4.0 mm).

FIG. 4B shows exemplary waveforms 450 and 452 illustrating outputs of a nominal buffer (Normal) and a 25 percent stronger buffer (Strong), respectively, driving an 8 mm wire segment, in accordance with aspects of the invention. When the clock distribution network is designed to minimize buffer PVT sensitivity, the buffer switches before the reflection arrives. When the reflection does arrive, it pulls the buffer output towards mid-supply, which may be VDD/2, thereby reducing the buffer delay. The PVT insensitivity can be explained by noting that when the buffer is stronger, with lower impedance, this reflected wave is less effective at pulling the buffer output back towards VDD/2, and the buffer delay actually increases. This apparent from the waveforms 450, 452, where the effect has been exaggerated by using a wire segment length of 8 mm having one sixth of the usual resistance.

In addition to the quarter-wave resonance frequency F_{Q}, higher-harmonic modes exist at odd multiples of F_{Q}. There are also resonances where the reflected signal makes an odd number of round trips through the wire in a half-cycle before returning to have a small effect on buffer delay: (F_{Q}/3, F_{Q}/5, . . . ). The wire segments employed in the present example are too lossy to observe any significant effects of harmonic frequencies, and therefore hypothetical wire segments having artificially low losses, such as, for example, ⅙th the resistive losses of actual wire segments, are simulated. These potential effects of harmonic frequencies for the illustrative case described above are shown graphically in FIG. 5, where a minimum sensitivity (0.0) occurs for wire segment lengths longer than each of the respective harmonic resonance lengths (e.g., wire segment lengths of about 6.5 mm, 12.0 mm, 21.0 mm, etc.).

By way of example only, a clock distribution network design for a POWER6™ (a trademark of IBM Corporation) microprocessor is optimized for frequencies exceeding 5 GHz using a compromise between duty cycle correction and PVT insensitivity, in accordance with the techniques of the present invention. The chip was fabricated using a 65 nanometer complementary metal-oxide-semiconductor (CMOS) process. The clock distribution network employs a length-matched tree with a path length of 19.2 mm from the clock source and requires eight levels of repowering buffers ending with 176 final buffers all driving a clock grid area of 88 mm² . FIG. 6 illustrates simulated (“X”) and measured (“O”) duty cycle correction results for the entire network at a clock frequency of 5 GHz. As apparent from the figure, measured results agree closely with simulation results in this instance. There is reduced duty cycle correction at 3 GHz and 4 GHz.

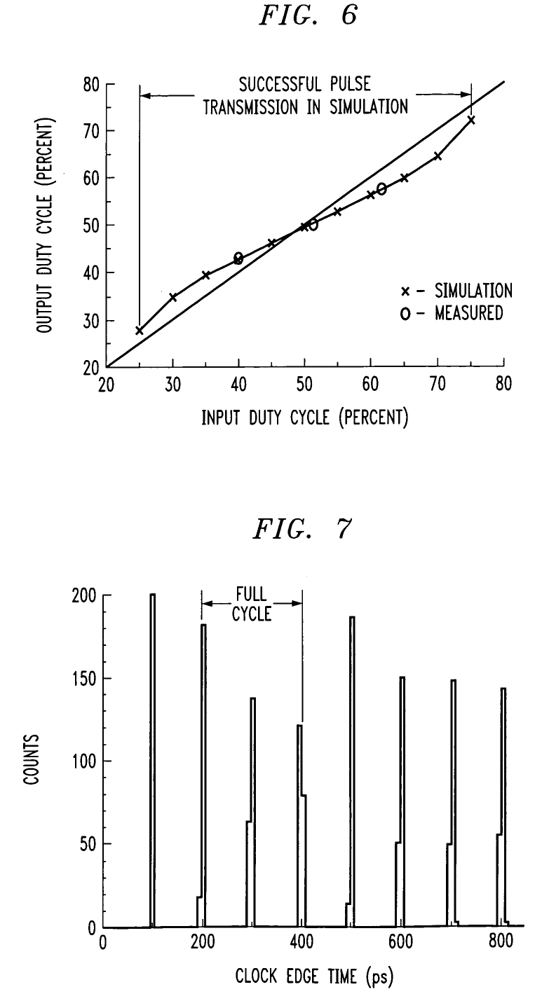

FIG. 7 is a histogram depicting exemplary results for 200 clock edge measurements at two different locations on the chip using on-chip measurement circuits (see, e.g., P. J. Restle et al., “Timing Uncertainty Measurements on the Power5 Microprocessor,” ISSCC Dig. Tech. Papers, pp. 354-355, February 2004, which is incorporated herein by reference), showing a final duty cycle of (49.5±0.5) percent at a clock frequency of 5 GHz, without the use of any additional active or passive duty cycle correction circuitry.

At least a portion of the methodologies of the present invention may be implemented in an integrated circuit. In forming integrated circuits, a plurality of identical die is typically fabricated in a repeated pattern on a surface of a semiconductor wafer. Each die includes a device described herein, and may include other structures and/or circuits. The individual die are cut or diced from the wafer, then packaged as an integrated circuit. One skilled in the art would know how to dice wafers and package die to produce integrated circuits. Integrated circuits so manufactured are considered part of this invention.

Although illustrative embodiments of the present invention have been described herein with reference to the accompanying drawings, it is to be understood that the invention is not limited to those precise embodiments, and that various other changes and modifications may be made therein by one skilled in the art without departing from the scope of the appended claims.

What is claimed is:

1. A clock distribution network for distributing a repetitive timing signal throughout an integrated circuit, the timing signal being within a range of frequencies about a first frequency, the distribution network comprising:
a plurality of buffer circuits; and
at least one conductive segment connecting a first buffer circuit of the plurality of buffer circuits to a second buffer circuit of the plurality of buffer circuits, the at least one conductive segment having a length selected so as to be less than a quarter-wave resonance length of the conductive segment at the first frequency to thereby achieve duty cycle correction.

2. The network of claim 1, wherein the length of the at least one conductive segment is selected such that a time taken for the timing signal to traverse the at least one conductive segment follows the relation
$$\frac{P}{8 n + 2} < T < \frac{P}{8 n - 2} ,$$
where T represents the time taken for the timing signal to traverse the at least one conductive segment, P represents a period of the timing signal, and n represents a positive integer based on at least one of harmonics of a resonance of the conductive segment and harmonics of a frequency of the timing signal.

3. The network of claim 1, wherein the length of the at least one conductive segment is selected such that a time taken for the timing signal to traverse the at least one conductive segment is less than about one sixth of a period of the timing signal and greater than about one tenth of the period of the timing signal.

4. The network of claim 1, wherein the length of the at least one conductive segment is selected such that a time taken for the timing signal to traverse the at least one conductive segment is substantially equal to about one eighth of a period of the timing signal.

5. The network of claim 1, wherein each of the buffer circuits has an input impedance and an output impedance associated therewith and the at least one conductive segment has a characteristic impedance associated therewith which is a function of the length of the conductive segment, the length of the conductive segment being selected such that the characteristic impedance of the conductive segment is substantially greater than the output impedance of a corresponding buffer connected to the conductive segment.

6. The network of claim 1, further comprising a plurality of conductive segments, each of the conductive segments being connected between respective pairs of buffers in a grid-based connection arrangement.

7. The network of claim 1, further comprising a plurality of conductive segments, each of the conductive segments being connected between respective pairs of buffers in a tree-based connection arrangement.

8. The network of claim 1, further comprising a plurality of conductive segments, each of the conductive segments being connected between respective pairs of buffers in a grid tree connection arrangement.

9. The network of claim 1, wherein at least one of the plurality of buffers comprises an inverter, an output impedance of the at least one buffer being a function of a strength of the inverter, the strength of the inverter being selected such that the output impedance of the buffer is at least about 30 percent less than a characteristic impedance of the conductive segment.

10. The network of claim 1, wherein the length of the at least one conductive segment is selected to be about 2.5 millimeters when the first frequency is about equal to 5 gigahertz.

11. A method of reducing duty cycle error of a repetitive timing signal in a clock distribution network including a plurality of buffers and a plurality of conductive segments, each of the plurality of conductive segments providing electrical connection between a respective pair of buffers in the plurality of buffers, the method comprising the steps of:
adjusting an output impedance of a first buffer of a given pair of buffers so that the output impedance of the first buffer is less than a characteristic impedance of a given one of the conductive segments, the first buffer having an output connected to a first end of the given conductive segment;
adjusting an input impedance of a second buffer of the given pair of buffers so that the input impedance of the second buffer is greater than the characteristic impedance of the given conductive segment, a second end of the given conductive segment being connected to an input of the second buffer; and
adjusting a length of the given conductive segment so that a time taken by the timing signal to traverse the given conductive segment is less than a quarter-wave resonance length of the conductive segment at a frequency of operation of the timing signal.

12. The method of claim 11, wherein the step of adjusting the length of the conductive segment comprises selecting the length of the conductive segment such that the time taken for the timing signal to traverse the conductive segment follows the relation
$$\frac{P}{8 n + 2} < T < \frac{P}{8 n - 2} ,$$
where T represents the time taken for the timing signal to traverse the at least one conductive segment, P represents a period of the timing signal, and n represents a positive integer based on at least one of harmonics of a resonance of the conductive segment and harmonics of a frequency of the timing signal.

13. The method of claim 11, wherein the step of adjusting the length of the conductive segment comprises selecting the length of the conductive segment such that the time taken for the timing signal to traverse the conductive segment is less than about one sixth of a period of the timing signal and greater than about one tenth of the period of the timing signal.

14. The method of claim 11, wherein the step of adjusting the length of the conductive segment comprises selecting the length of the conductive segment such that the time taken for the timing signal to traverse the conductive segment is equal to about one eighth of a period of the timing signal.

15. The method of claim 11, further comprising the step of optimizing a length of each of the plurality of conductive segments using simulation to thereby achieve a prescribed amount of duty cycle correction.

16. An integrated circuit comprising at least one clock distribution network for distributing a repetitive timing signal throughout the integrated circuit, the timing signal being within a range of frequencies about a first frequency, the at least one clock distribution network comprising:
a plurality of buffer circuits; and
at least one conductive segment connecting a first buffer circuit of the plurality of buffer circuits to a second buffer circuit of the plurality of buffer circuits, the at least one conductive segment having a length selected so as to be less than a quarter-wave resonance length of the conductive segment at the first frequency to thereby achieve duty cycle correction.

17. The integrated circuit of claim 16, wherein the length of the at least one conductive segment is selected such that a time taken for the timing signal to traverse the at least one conductive segment follows the relation
$$\frac{P}{8 n + 2} < T < \frac{P}{8 n - 2} ,$$
where T represents the time taken for the timing signal to traverse the at least one conductive segment, P represents a period of the timing signal, and n represents a positive integer based on at least one of harmonics of a resonance of the conductive segment and harmonics of a frequency of the timing signal.

18. The integrated circuit of claim 16, wherein the length of the at least one conductive segment is selected such that a time taken for the timing signal to traverse the at least one conductive segment is less than about one sixth of a period of the timing signal and greater than about one tenth of the period of the timing signal.

19. The integrated circuit of claim 16, wherein the length of the at least one conductive segment is selected such that a time taken for the timing signal to traverse the at least one conductive segment is substantially equal to about one eighth of a period of the timing signal.

20. The integrated circuit of claim 16, wherein each of the buffer circuits has an input impedance and an output impedance associated therewith and the at least one conductive segment has a characteristic impedance associated therewith which is a function of the length of the conductive segment, the length of the conductive segment being selected such that the characteristic impedance of the conductive segment is substantially greater than the output impedance of a corresponding buffer connected to the conductive segment.
